(19) United States
(12) Patent Application Publication
(10) Pub. No.: US 2026/0314190 A1
(43) Pub. Date: Oct. 8, 2026

(54) DISPLAY PANEL AND DISPLAY DEVICE

(71) Applicant: HKC CORPORATION LIMITED, Shenzhen (CN)

(72) Inventors: Yangling TANG, Shenzhen (CN); Zhisheng XIE, Shenzhen (CN); Qin LIANG, Shenzhen (CN); Haijiang YUAN, Shenzhen (CN)

(21) Appl. No.: 19/573,394

(22) Filed: Mar. 20, 2026

(30) Foreign Application Priority Data
Apr. 3, 2025 (CN) 202510418724.6

(51) Int. Cl. H10K 59/126; H10K 59/122; H10K 59/38; H10K 59/80

(52) U.S. Cl. CPC H10K 59/126; H10K 59/122; H10K 59/38; H10K 59/873

(57) ABSTRACT

The display panel includes a base substrate, a pixel defining layer, display light-emitting structures, dimming structures, and a first encapsulation layer. Each of the display light-emitting structures includes a display light-emitting diode, which includes a display light-emitting portion configured to emit display light. Each of the dimming structures includes a dimming light-emitting diode provided with a dimming light-emitting portion and a light-shielding portion. A light-emitting color of the dimming light-emitting portion is different from a light-emitting color of at least one display light-emitting portion adjacent to the dimming light-emitting portion. The first encapsulation layer includes adjustment areas. The dimming light-emitting portion on an edge emits a light ray parallel to the inclination angle of the first inclined surface. The light ray forms a light-emitting point with a top surface of one of the adjustment areas.

### CROSS-REFERENCE TO RELATED APPLICATIONS

This application claims priority to Chinese Application No. 202510418724.6, filed on Apr. 3, 2025, the entire disclosure of which is hereby incorporated herein by reference.

### TECHNICAL FIELD

The present disclosure belongs to the field of display technology, and specifically relates to a display panel and a display device.

### BACKGROUND

With the growing awareness of confidentiality protection among users, there is a significant market demand for privacy protection technology in display devices. In terms of conventional privacy protection display, a privacy protection film is attached to a surface of a display. The privacy protection film uses an ultra-micro louver technology, which is similar in principle to vertical blinds. This privacy protection method is simple and convenient, but it severely affects visual performance.

Currently, a black matrix (BM) structure is used to form a privacy pixel structure of an organic light-emitting diode, thereby achieving a privacy protection mode. However, this mode will result in high brightness at small viewing angles and low brightness at privacy protection viewing angles, causing a reduced number of privacy protection light rays at privacy protection viewing angles, which in turn leads to poor privacy protection performance.

### SUMMARY

An objective of the present disclosure is to solve the problem in the related art that a black matrix privacy pixel structure has high brightness at small viewing angles and low brightness at privacy protection viewing angles, resulting in a reduced number of privacy protection light rays at privacy protection viewing angles and thus poor privacy protection performance.

In a first aspect of the present disclosure, provided is a display panel, including a base substrate, the base substrate having a display area, where the display panel further includes: a pixel defining layer, where the pixel defining layer is provided with pixel defining portions and a plurality of pixel openings spaced apart from each other, each of the pixel defining portions being located between the adjacent pixel openings, and in a direction from the base substrate to the pixel defining layer, distances between adjacent pixel defining portions gradually increasing; a plurality of display light-emitting structures, where each of the plurality of display light-emitting structures includes a display light-emitting diode, where the display light-emitting diode includes a display light-emitting portion, and at least part of the display light-emitting portion is located within one of the plurality of pixel openings; a plurality of dimming structures, where each of the plurality of dimming structures is disposed between the adjacent display light-emitting structures; each of the plurality of dimming structures includes a dimming light-emitting diode and a light-shielding portion, where the dimming light-emitting diode includes a dimming light-emitting portion, and at least part of the dimming light-emitting portion is located within one of the plurality of pixel openings; the light-shielding portion is disposed on a side of the dimming light-emitting diode away from the base substrate; an orthographic projection of the dimming light-emitting portion on the base substrate is located within an orthographic projection of the light-shielding portion on the base substrate, and a light-emitting color of the dimming light-emitting portion is different from a light-emitting color of at least one display light-emitting portion adjacent to the dimming light-emitting portion; and a first encapsulation layer, disposed on a side of the light-shielding portions toward the base substrate, and configured to cover the display light-emitting diodes, the dimming light-emitting diodes, and the pixel defining layer, where the first encapsulation layer includes adjustment areas, an orthographic projection of each of the adjustment areas on the base substrate is located within an orthographic projection of the light-shielding portion on the base substrate, each of the adjustment areas is provided with a first inclined surface, and an inclination angle of the first inclined surface ranges from 35° to 50°, where the dimming light-emitting portion located on an edge of each of the plurality of pixel openings emits a light ray parallel to the inclination angle of the first inclined surface, the light ray forming a light-emitting point with a top surface of one of the adjustment areas, and a line connecting the light-emitting point and a bottom edge of the light-shielding portion forming a first included angle with a top surface of the first encapsulation layer. The first included angle is greater than or equal to the inclination angle of the first inclined surface.

In a second aspect of the present disclosure, provided is a display device, including: a driving chip; and a display panel, where the display panel is electrically connected to the driving chip. The display device includes: a driving chip; and a display panel electrically connected to the driving chip; where the display panel includes a base substrate, and the base substrate has a display area, where the display panel further includes: a pixel defining layer provided with pixel defining portions and a plurality of pixel openings spaced apart from each other, each of the pixel defining portions being located between adjacent pixel openings, and in a direction from the base substrate to the pixel defining layer, distances between adjacent pixel defining portions gradually increasing; a plurality of display light-emitting structures, each of the plurality of display light-emitting structures including a display light-emitting diode, the display light-emitting diode including a display light-emitting portion, and at least part of the display light-emitting portion being located within one of the plurality of pixel openings; a plurality of dimming structures, each of the plurality of dimming structures being disposed between adjacent display light-emitting structures; and each of the plurality of dimming structures including a dimming light-emitting diode and a light-shielding portion, where the dimming light-emitting diode includes a dimming light-emitting portion, and at least part of the dimming light-emitting portion is located within one of the plurality of pixel openings; the light-shielding portion being located on a side of the dimming light-emitting diode away from the base substrate; an orthographic projection of the dimming light-emitting portion on the base substrate being located within an orthographic projection of the light-shielding portion on the base substrate; and a light-emitting color of the dimming light-emitting portion being different from a light-emitting color of at least one display light-emitting portion adjacent to the dimming light-emitting portion; and a first encapsulation layer disposed on a side of the light-shielding portion toward the base substrate, and configured to cover the display light-emitting diode, the dimming light-emitting diode, and the pixel defining layer, where the first encapsulation layer includes adjustment areas, and an orthographic projection of each of the adjustment areas on the base substrate is located within an orthographic projection of the light-shielding portion on the base substrate; where each of the adjustment areas is provided with a first inclined surface, and an inclination angle of the first inclined surface ranges from 35° to 50°; where the dimming light-emitting portion located on an edge of each of the plurality of pixel openings emits a light ray parallel to the inclination angle of the first inclined surface, the light ray forming a light-emitting point with a top surface of one of the adjustment areas, and a line connecting the light-emitting point and a bottom edge of the light-shielding portion forming a first included angle with a top surface of the first encapsulation layer, where the first included angle is greater than or equal to the inclination angle of the first inclined surface.

Other features and advantages of the present disclosure will become apparent from the following detailed description, or may be learned in part through the practice of the present disclosure.

It should be understood that the above general description and the following detailed description are merely exemplary and explanatory, and do not limit the present disclosure.

### BRIEF DESCRIPTION OF DRAWINGS

The drawings herein are incorporated into and constitute a part of the specification, illustrating embodiments in accordance with the present disclosure, and together with the specification serve to explain the principles of the present disclosure. It is apparent that the drawings described below are merely some embodiments of the present disclosure. For those of ordinary skill in the art, other drawings may be obtained based on these drawings without making creative effort.

FIG. 1 illustrates a schematic diagram of an arrangement of display light-emitting structures and dimming structures on a base substrate according to Embodiment I or II of the present disclosure.

FIG. 2 illustrates a cross-sectional schematic structural diagram of a display panel according to Embodiment I or II of the present disclosure.

FIG. 3 illustrates a cross-sectional schematic structural diagram of a dimming structure according to Embodiment I or II of the present disclosure.

FIG. 4 illustrates a diagram of a path of a light ray emitted from a dimming light-emitting portion at an inclination angle of a first inclined surface of 30° in the related art.

FIG. 5 illustrates an experimental diagram of a path of light emitted from a dimming light-emitting portion at an inclination angle of a first inclined surface of 30° in the related art.

FIG. 6 illustrates a diagram of a path of a light ray emitted from a dimming light-emitting portion at an inclination angle of a first inclined surface of 45° in the related art.

FIG. 7 illustrates an experimental diagram of a path of light emitted from a dimming light-emitting portion at an inclination angle of a first inclined surface of 45° in the related art.

FIG. 8 illustrates a diagram of a path of a light ray emitted from a dimming light-emitting portion at an inclination angle of a first inclined surface of 60° in the related art.

FIG. 9 illustrates an experimental diagram of a path of light emitted from a dimming light-emitting portion at an inclination angle of a first inclined surface of 60° in the related art.

FIG. 10 illustrates a cross-sectional schematic structural diagram of a third inclined surface, which is an arc surface according to Embodiment I or II of the present disclosure.

FIG. 11 illustrates a cross-sectional schematic structural diagram of a display panel further including a touch electrode layer, a color resist layer, and a planarization layer according to Embodiment I or II of the present disclosure.

FIG. 12 illustrates a schematic structural diagram of a connection between the display panel and a driving chip according to Embodiment I or II of the present disclosure.

### DETAILED DESCRIPTION OF THE EMBODIMENTS

The exemplary embodiments will now be described more comprehensively with reference to the accompanying drawings. However, the exemplary embodiments may be implemented in various forms and should not be construed as limited to the examples set forth herein; rather, these embodiments are provided so that the present disclosure will be more thorough and complete, and will fully convey the concept of the exemplary embodiments to those skilled in the art.

In the present disclosure, the terms “first” and “second” are used merely for descriptive purposes and should not be construed as indicating or implying relative importance or implicitly indicating the number of technical features referred to. Thus, features defined as “first” or “second” may expressly or implicitly include one or more of such features. In the description of the present disclosure, “a plurality of” means two or more, unless otherwise specifically defined.

In the present disclosure, unless otherwise specified, terms such as “assembly” and “connection” should be understood broadly. For example, they may refer to fixed connections, detachable connections, or integral connections; mechanical connections or electrical connections; direct connections or indirect connections via intermediate media; internal communication between two elements or interaction between two elements. For those of ordinary skill in the art, the specific meaning of the above terms in the present disclosure may be understood according to the specific circumstances.

In addition, the described features, structures, or characteristics may be combined in any suitable manner in one or more embodiments. In the following description, numerous specific details are provided to give a thorough understanding of the embodiments of the present disclosure. However, those skilled in the art will recognize that the technical solutions of the present disclosure may be practiced without one or more of the specific details, or other methods, components, devices, steps, etc. may be used. In other cases, well-known methods, devices, implementations, or operations are not shown or described in detail to avoid obscuring aspects of the present disclosure.

### Embodiment I

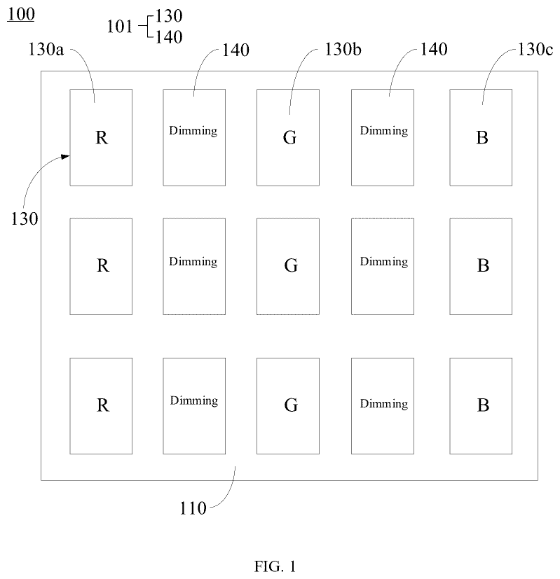

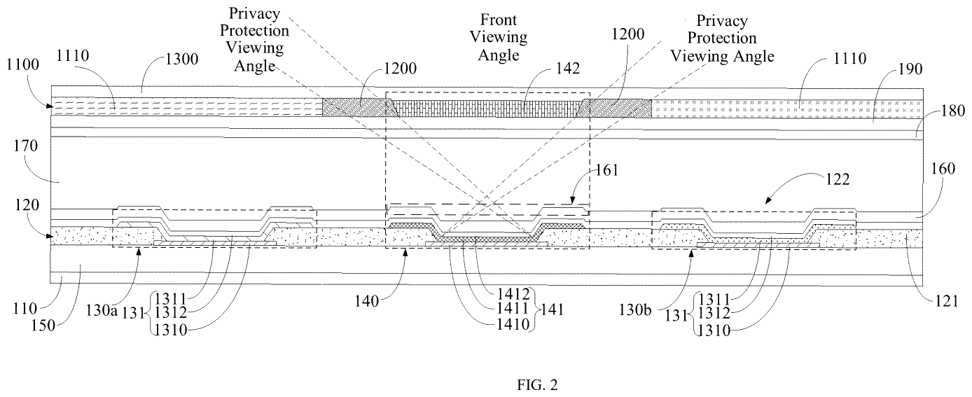

FIG. 1 illustrates a schematic diagram of an arrangement of display light-emitting structures and dimming structures on a base substrate. FIG. 2 illustrates a cross-sectional schematic structural diagram of a display panel.

Embodiment I of the present disclosure provides a display panel 100. The display panel 100 may be an organic light-emitting diode (OLED) display. Referring to FIG. 1 and FIG. 2, the display panel 100 may include a base substrate 110, a pixel defining layer 120, a plurality of display light-emitting structures 130, and a plurality of dimming structures 140. The base substrate 110 has a display area 101 and a non-display area, where the non-display area may surround the display area 101. The pixel defining layer 120, the plurality of display light-emitting structures 130, and the plurality of dimming structures 140 may be disposed in the display area 101 on the base substrate 110. The display area 101 may include areas corresponding to the plurality of light-emitting structures 130 and areas corresponding to the plurality of dimming structures 140.

It should be understood that, as shown in FIG. 2, the display panel 100 may further include a driving circuit layer 150. This driving circuit layer 150 may be formed on the base substrate 110 prior to the pixel defining layer 120, the plurality of display light-emitting structures 130, and the plurality of dimming structures 140. The driving circuit layer 150 may include circuit structures such as thin film transistors and wiring, which are configured to drive the light-emitting diodes mentioned later. Further details are omitted here.

For example, the base substrate 110 may be a rigid substrate made of glass, but is not limited thereto; the base substrate may also be a flexible substrate made of materials such as polyimide (abbreviated as PI). In other words, the display panel 100 of the present disclosure is not limited to a rigid, non-bendable panel, but may also be a flexible, bendable panel.

As shown in FIG. 2, the pixel defining layer 120 may be provided with pixel defining portions and a plurality of pixel openings 122 spaced apart (not labeled in the figure), and each of pixel defining portions 121 is located between adjacent pixel openings 122. In other words, the pixel defining layer 120 as a whole may be regarded as a grid-like hollow structure layer, where a plurality of hollow regions are the plurality of pixel openings 122 for forming pixels in this embodiment, and the non-hollow regions are the pixel defining portions 121. It should be understood that the surface of the pixel defining portion 121 facing away from the base substrate 110 is planar. For example, the pixel defining layer 120 may be made of materials such as PI.

In this embodiment of the present disclosure, as shown in FIG. 2, in a direction from the base substrate 110 to the pixel defining layer 120, a distance between adjacent pixel defining portions 121 gradually increases. Exemplarily, a cross-section of the pixel defining portion 121 in a thickness direction of the base substrate 110 is of a trapezoidal structure.

As shown in FIG. 2, the plurality of display light-emitting structures 130 each may include a display light-emitting diode 131, and the display light-emitting diode 131 includes a display anode 1310, a display light-emitting portion 1311, and a display cathode 1312 which are stacked in sequence in a direction away from the base substrate 110.

It should be understood that display anodes 1310 of each of the display light-emitting diodes 131 in the display panel 100 are spaced apart, such that each of the display light-emitting diodes 131 may be independently driven. The display cathodes 1312 of each of the display light-emitting diodes 131 may be connected together to form a planar electrode, thereby reducing the manufacturing cost.

As shown in FIG. 2, the display anodes 1310 are formed between the base substrate 110 and the pixel defining layer 120. That is, during the manufacturing process of the display panel 100, the display anodes 1310 are first formed on the base substrate 110, and then the pixel defining layer 120 is manufactured. The pixel defining portion 121 covers edge areas of the display anodes 1310, and the edge areas of the display anodes 1310 may be connected to structures such as thin film transistors in the driving circuit layer 150. The plurality of pixel openings 122 expose the central areas of the display anodes 1310, and a part of the display light-emitting portion 1311 is located within each of the plurality of pixel openings 122 and contacts the central area of each of the display anodes 1310.

As shown in FIG. 2, a part of the display light-emitting portion 1311 may be located within each of the plurality of pixel openings 122, and the other part thereof may be located on a side of the pixel defining portion 121 away from the base substrate 110, that is, a top surface of the pixel defining portion 121. In other words, during the manufacturing of the display panel 100, the pixel defining layer 120 may be manufactured first, and after the pixel defining layer 120 is manufactured, the display light-emitting portion 1311 is formed, such that the display light-emitting portion 1311 is formed both within each of the plurality of pixel openings 122 and on the top surface of the pixel defining portion 121. For example, the display light-emitting portion 1311 may be formed within each of the plurality of pixel openings 122 and on the top surface of the pixel defining portion 121 by methods such as vapor deposition.

It may be understood that the display light-emitting portion 1311 located on the top surface of the pixel defining portion 121 does not emit light.

In addition, the display light-emitting portion 1311 may include a hole injection layer, a hole transport layer, an organic light-emitting material layer, an electron transport layer, and an electron injection layer stacked in sequence. The hole injection layer contacts the display anode 1310, and the electron injection layer contacts the display cathode 1312. But not limited thereto, the display light-emitting portion 1311 may also include only a hole transport layer, a light-emitting material layer, and an electron transport layer, or other structures, depending on actual requirements.

As shown in FIG. 2, the display cathode 1312 may be formed after the display light-emitting portion 1311 is formed and contacts the display light-emitting portion 1311. The display cathode 1312 may include a low work function material layer containing Li, Ca, LiF/Ca, LiF/Al, Al, Mg, Ag, Pt, Pd, Ni, Au, Nd, Ir, Cr, BaF₂, Ba, and compounds or mixtures thereof. For example, the display cathode 1312 may include a low work function material layer made from a mixture of Ag and Mg.

It should be understood that, as shown in FIGS. 1 and 2, a plurality of display light-emitting structures 130 may be disposed according to this embodiment, and the display light-emitting portion 1311 in each of the display light-emitting diodes 131 of each of the plurality of display light-emitting structures 130 is correspondingly located within a pixel opening 122.

In this embodiment, as shown in FIGS. 1 and 2, the plurality of display light-emitting structures 130 in the display panel 100 may include various types, and light-emitting colors of the display light-emitting portions 1311 of different types of the plurality of display light-emitting structures 130 are different. For example: a red-type display light-emitting structure 130a, a green-type display light-emitting structure 130b, and a blue-type display light-emitting structure 130c. The red-type display light-emitting structure 130a refers to the display light-emitting portion 1311 emitting red light, the green-type display light-emitting structure 130b refers to the display light-emitting portion 1311 emitting green light, and the blue-type display light-emitting structure 130c refers to the display light-emitting portion 1311 emitting blue light.

In this embodiment, each of the plurality of dimming structures 140 is located between adjacent display light-emitting structures 130 and spaced apart from each of the plurality of display light-emitting structures 130.

For example, as shown in FIG. 1, a dimming structure 140 is disposed between the red-type display light-emitting structure 130a and the green-type display light-emitting structure 130b, and another dimming structure 140 is disposed between the green-type display light-emitting structure 130b and the blue-type display light-emitting structure 130c. The two dimming structures 140 mutually adjust the adjacent display light-emitting structures 130 to achieve privacy protection and enhance the display brightness.

Both the display light-emitting structures 130 and the plurality of dimming structures 140 may be understood as subpixels in the display panel 100. The red-type display light-emitting structure 130a, the green-type display light-emitting structure 130b, two dimming structures 140, and the blue-type display light-emitting structure 130c may form a pixel unit. The arrangement of pixels within the pixel unit may be: the red-type display light-emitting structure 130a, the dimming structure 140, the green-type display light-emitting structure 130b, the dimming structure 140, the blue-type display light-emitting structure 130c, as shown in FIG. 1.

As shown in FIG. 2, each of the plurality of dimming structures 140 includes a dimming light-emitting diode 141. The dimming light-emitting diode 141 may include a dimming anode 1410, a dimming light-emitting portion 1411, and a dimming cathode 1412 stacked in sequence in the direction away from the base substrate 110. Part of the dimming light-emitting portion 1411 may be formed on a surface of the pixel defining portion 121 away from the base substrate 110, and another part thereof may be formed within the pixel opening 122. It may be understood that, during the manufacturing of the display panel 100, the pixel defining layer 120 may be manufactured first, followed by the dimming light-emitting portion 1411.

The dimming light-emitting portion 1411 may be arranged in the same layer as the display light-emitting portion 1311 of one type of display light-emitting structure 130. For example, when the display panel 100 includes the red-type display light-emitting structure 130a, the green-type display light-emitting structure 130b, and the blue-type display light-emitting structure 130c, the dimming light-emitting portion 1411 may be arranged in the same layer as the display light-emitting portion 1311 of the red-type display light-emitting structure 130a, and thus the light-emitting color of the dimming light-emitting portion 1411 is also correspondingly red; or, the dimming light-emitting portion 1411 may be arranged in the same layer as the display light-emitting portion 1311 of the green-type display light-emitting structure 130b, and thus the light-emitting color of the dimming light-emitting portion 1411 is also correspondingly green; or, the dimming light-emitting portion 1411 may be arranged in the same layer as the display light-emitting portion 1311 of the blue-type display light-emitting structure 130c, and thus the light-emitting color of the dimming light-emitting portion 1411 is also correspondingly blue.

In this embodiment, the dimming light-emitting portion 1411 is arranged in the same layer as the display light-emitting portion 1311 of one type of display light-emitting structure 130, which helps reduce the production cost.

It may be understood that the light-emitting color of the dimming light-emitting portion 1411 is different from the light-emitting color of at least one display light-emitting portion 1311 adjacent to the dimming light-emitting portion. For example, when the dimming structure 140 is located between the red-type display light-emitting structure 130a and the green-type display light-emitting structure 130b, the light-emitting color of the dimming light-emitting portion 1411 is blue; and when the dimming structure 140 is located between the green-type display light-emitting structure 130b and the blue-type display light-emitting structure 130c, the light-emitting color of the dimming light-emitting portion 1411 is red. But not limited thereto, the light-emitting color of the dimming light-emitting portion 1411 may also be other types of colors, such as yellow and white.

In this embodiment, as shown in FIG. 2, the dimming light-emitting portion 1411 and the display light-emitting portion 1311 may be arranged at intervals from each other, which may prevent crosstalk between the dimming light-emitting portion 1411 and the display light-emitting portion 1311.

It should be understood that, as shown in FIG. 2, the dimming anode 1410 may be arranged in the same layer as the display anode 1310 and may be formed on a side of the driving circuit layer 150 away from the base substrate 110. The pixel defining portion 121 covers the edge area of the dimming anode 1410, and the edge area of the dimming anode 1410 may be connected to the thin film transistor structure in the driving circuit layer 150 to transmit electrical signals to the dimming anode 1410. The pixel opening 122 exposes the central area of the dimming anode 1410, and the portion of the dimming light-emitting portion 1411 located within the pixel opening 122 contacts the central area of the dimming anode 1410.

For example, the dimming anode 1410 may be a high work function material layer, which may include indium tin oxide (ITO), indium zinc oxide (IZO), zinc oxide (ZnO), or indium oxide (In₂O₃).

The dimming cathode 1412 may be formed on a surface of the dimming light-emitting portion 1411 away from the dimming anode 1410. That is, during the manufacturing of the display panel 100, the dimming light-emitting portion 1411 may be formed first on the base substrate 110, followed by the dimming cathode 1412, and the dimming cathode 1412 contacts the surface of the dimming light-emitting portion 1411 away from the dimming anode 1410.

For example, the dimming cathode 1412 may include a low work function material layer containing Li, Ca, LiF/Ca, LiF/Al, Al, Mg, Ag, Pt, Pd, Ni, Au, Nd, Ir, Cr, BaF₂, Ba, compounds, or mixtures thereof. For instance, the dimming cathode 1412 may include a low work function material layer made from a mixture of Ag and Mg.

As shown in FIG. 2, the dimming cathode 1412 may be arranged in the same layer as and connected to the display cathode 1312 to form a planar electrode, thereby reducing the manufacturing difficulty and cost.

In this embodiment, as shown in FIG. 2, the dimming structure 140 further includes a light-shielding portion 142. The light-shielding portion 142 may be located on a side of the dimming light-emitting diode 141 away from the base substrate 110. The light-shielding portion 142 is configured to block the dimming light-emitting portion 1411 of the dimming light-emitting diode 141. That is, an orthographic projection of the dimming light-emitting portion 1411 on the base substrate 110 is within an orthographic projection of the light-shielding portion 142 on the base substrate 110, and the light-emitting color of the dimming light-emitting portion 1411 is different from the light-emitting color of the adjacent display light-emitting portion 1311.

In the solution of the present disclosure, the dimming structure 140 is additionally disposed in the display panel 100. This dimming structure 140 includes a dimming light-emitting diode 141 and a light-shielding portion 142. The light-shielding portion 142 blocks the dimming light-emitting portion 1411 of the dimming light-emitting diode 141. Thus, when both the dimming light-emitting diode 141 and the display light-emitting diode 131 are emitting light, due to the presence of the light-shielding portion 142, when viewed from the front, the light emitted by the dimming light-emitting diode 141 is blocked by the light-shielding portion 142, and only the light emitted by the display light-emitting diode 131 may be seen. In other words, the display image viewed from a front viewing angle is a normal display image. However, when viewed from an oblique angle, both the light emitted by the display light-emitting diode 131 and the light emitted by the dimming light-emitting diode 141 may be seen. Since the color of the light emitted by the dimming light-emitting diode 141 is different from the color of the adjacent display light-emitting diode 131, the light ray from the dimming light-emitting diode 141 mixes with the light ray from the adjacent display light-emitting diode 131, resulting in display color distortion and interference with information reading. In other words, the display image viewed from an oblique angle is a privacy protection image.

The light-shielding portion 142 may be a black matrix (BM), that is, the light-shielding portion is made of a black material to enhance the blocking effect of the dimming light-emitting diode 141 when viewed from the front viewing angle, thereby ensuring the normal display image is seen from the front viewing angle.

It is worth noting that the dimming anode 1410 may be disconnected from the display anode 1310, allowing the dimming light-emitting diode 141 and the display light-emitting diode 131 to be independently controlled. This enables the display panel 100 to have both a normal display mode and a privacy protection display mode, and the display panel 100 of this embodiment may achieve one-click privacy protection switching.

For example, when the display panel 100 is in the normal display mode, the display light-emitting diode 131 is controlled to emit light, and the dimming light-emitting diode 141 is controlled not to emit light, such that the normal display image may be seen from both the front and oblique angles. When the display panel 100 is switched from the normal display mode to the privacy protection display mode, both the display light-emitting diode 131 and the dimming light-emitting diode 141 are controlled to emit light. Due to the presence of the light-shielding portion 142, when viewed from the front viewing angle, the light ray emitted by the dimming light-emitting diode 141 is blocked by the light-shielding portion 142, and only the light emitted by the display light-emitting diode 131 may be seen. In other words, the display image viewed from the front viewing angle is the normal display image. However, when viewed from the oblique angle, both the light emitted by the display light-emitting diode 131 and the light ray emitted by the dimming light-emitting diode 141 may be seen. Since the color of the light emitted by the dimming light-emitting diode 141 is different from the color of the adjacent display light-emitting diode 131, the light ray from the dimming light-emitting diode 141 mixes with the light ray from the adjacent display light-emitting diode 131, resulting in color distortion and interfering with information reading. In other words, the display image viewed from an oblique angle is a privacy protection image.

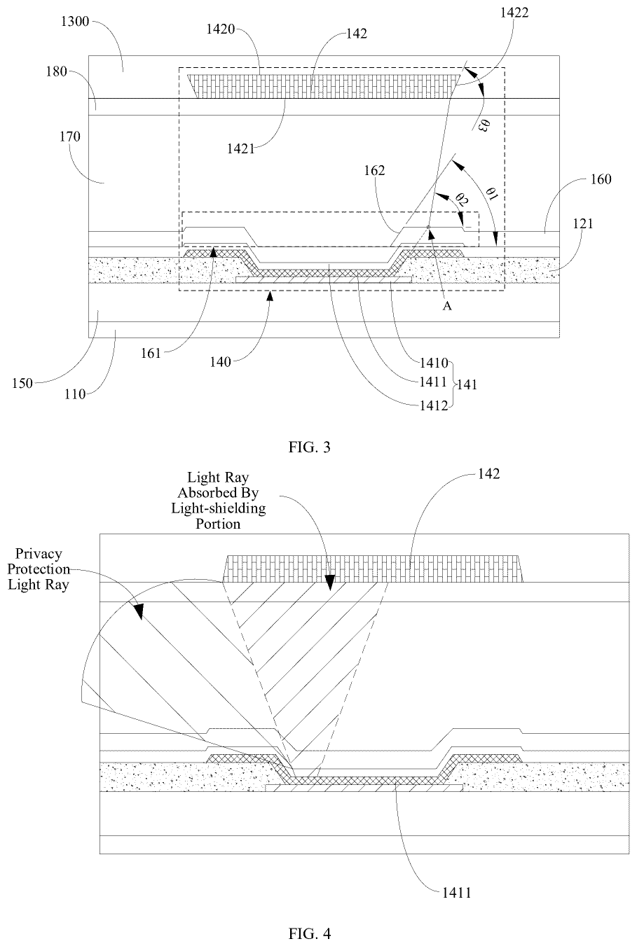

FIG. 3 shows a schematic cross-sectional view of the dimming structure.

In this embodiment, referring to FIG. 3, the display panel 100 further includes a first encapsulation layer 160. The first encapsulation layer 160 is disposed on a side of the light-shielding portion 142 adjacent to the base substrate 110, and covers the display light-emitting diode 131, the dimming light-emitting diode 141, and the pixel defining layer 120. The first encapsulation layer 160 includes adjustment areas 161. A first inclined surface 162 is disposed within each of the adjustment areas 161. An inclination angle θ1 of the first inclined surface 162 is an acute angle, which means that each of the adjustment areas 161 of the first encapsulation layer 160 has a slope, and this slope is at an acute angle.

In this embodiment, referring to FIG. 3, the dimming light-emitting portion 1411 located at an edge of the pixel opening 122 may emit a light ray parallel to the inclination angle of the first inclined surface 162. That is, at the position of the dimming light-emitting portion 1411 toward the pixel defining portion 121, the light ray may be emitted parallel to the slope, and this light ray may form a light-emitting point A with the top surface of the first encapsulation layer 160. The line connecting this light-emitting point A and the bottom edge of the light-shielding portion 142 forms a first angle θ2 with the top surface of the first encapsulation layer 160.

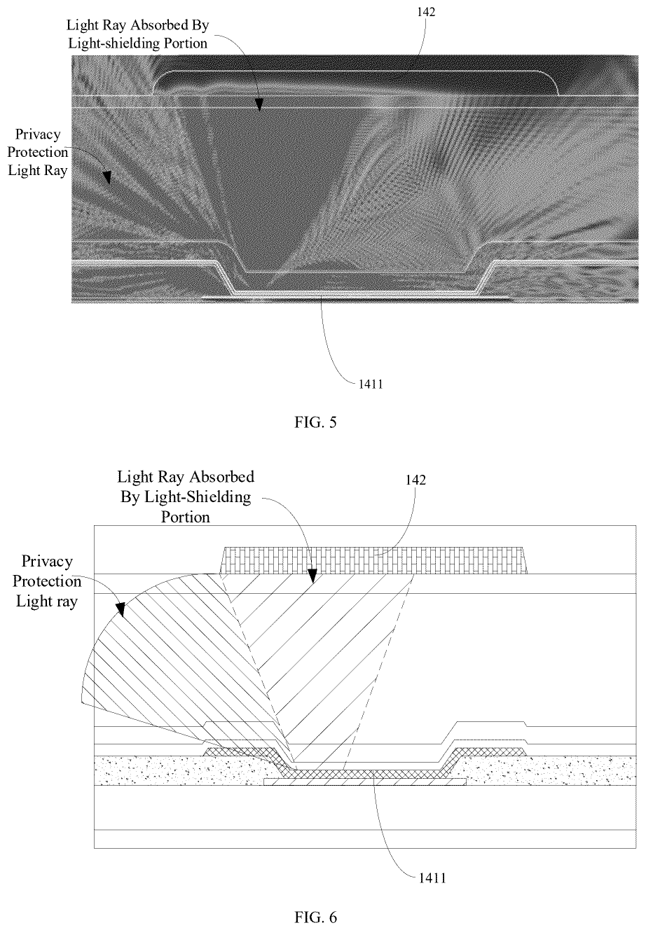

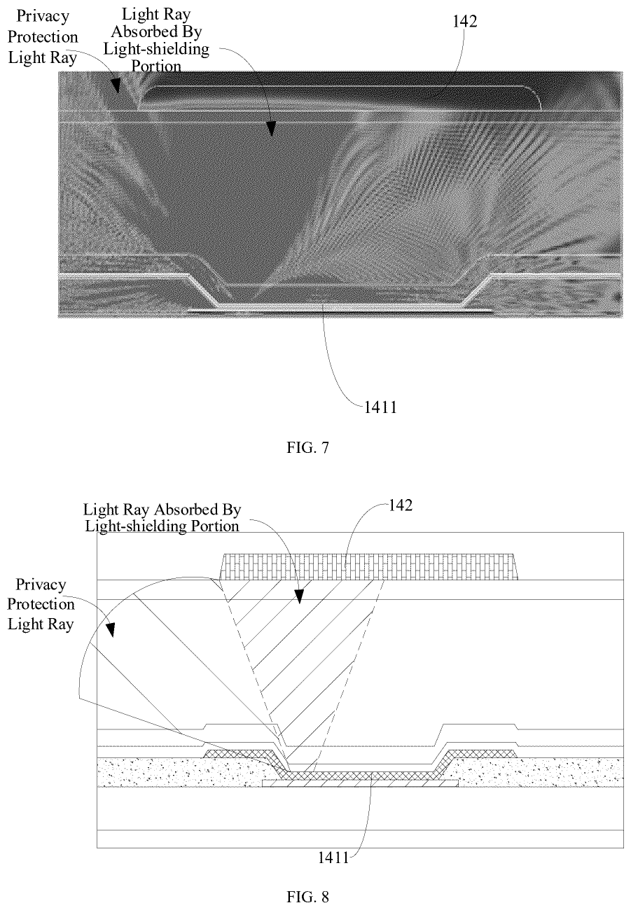

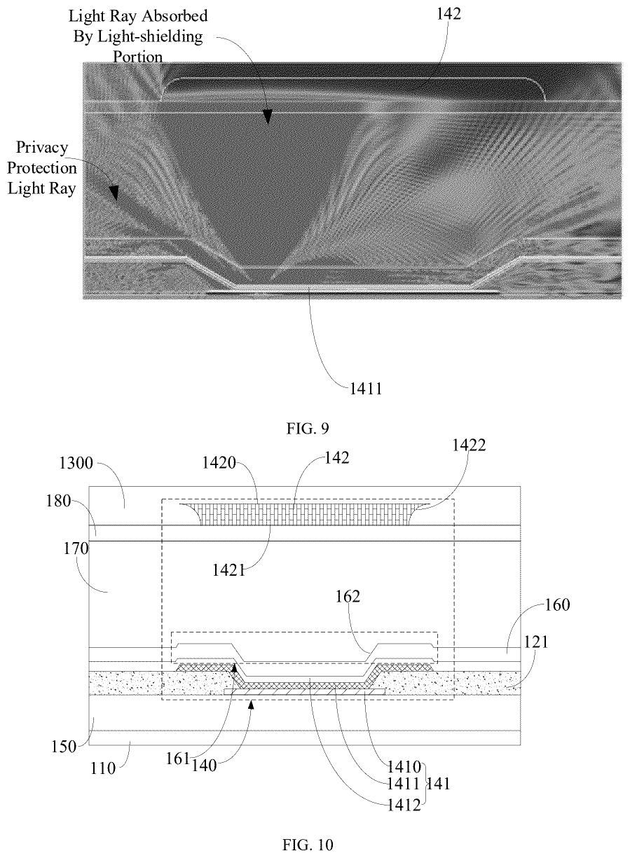

FIG. 4 illustrates a diagram of a path of a light ray emitted from a dimming light-emitting portion at an inclination angle of a first inclined surface of 30° in the related art. FIG. 5 illustrates an experimental diagram of a path of light emitted from a dimming light-emitting portion at an inclination angle of a first inclined surface of 30° in the related art. FIG. 6 illustrates a diagram of a path of a light ray emitted from a dimming light-emitting portion at an inclination angle of a first inclined surface of 45° in the related art. FIG. 7 illustrates an experimental diagram of a path of light emitted from a dimming light-emitting portion at an inclination angle of a first inclined surface of 45° in the related art. FIG. 8 illustrates a diagram of a path of a light ray emitted from a dimming light-emitting portion at an inclination angle of a first inclined surface of 60° in the related art. FIG. 9 illustrates an experimental diagram of a path of light emitted from a dimming light-emitting portion at an inclination angle of a first inclined surface of 60° in the related art.

Due to the light guiding effect of the first encapsulation layer 160, most of the light rays emitted by the dimming light-emitting portion 1411 are emitted at a small viewing angle (display viewing angle), and since a light-shielding portion 142 is provided above the small viewing angle (display viewing angle), most of the light rays from the dimming light-emitting portion 1411 are absorbed by the light-shielding portion 142. Only a small part of the light rays is emitted at a large viewing angle (privacy protection viewing angle) for privacy protection, resulting in low brightness at the privacy protection viewing angle, and thus poor privacy protection performance.

In FIG. 4, FIG. 6, and FIG. 8, the denser the hatching lines in the privacy protection light ray area, the more light rays emitted for privacy protection; on the contrary, the sparser the hatching lines, the fewer light rays emitted. As shown in FIGS. 4 to 9, it may be seen that at a 45° inclination of the first inclined surface, more privacy protection light rays are emitted in the privacy protection light ray region compared to 30° and 60°. Moreover, most of the dimming light emitted by the dimming light-emitting portion 1411 is absorbed by the light-shielding portion 142, and only a small part of the dimming light rays may be emitted and mixed with the display light rays emitted by the adjacent display light-emitting portion 1311. This results in fewer privacy protection light rays at the privacy protection viewing angle, leading to degraded privacy protection performance.

Therefore, in this disclosure, the light outputs at the small viewing angle and the large viewing angle (the privacy protection viewing angle) are adjusted by adjusting the inclination angle θ1 of the first inclined surface 162 and a relationship between the first included angle θ2 and the inclination angle θ1 of the first inclined surface 162.

In this embodiment, the inclination angle θ1 of the first inclined surface 162 ranges from 35° to 50°, for example, 35°, 40°, 45°, or 50°. The first angle θ2 is greater than or equal to the inclination angle θ1 of the first inclined surface 162, so as to reduce the light rays entering the light-shielding portion 142 at small viewing angles (display viewing angles), increase the light rays emitted at large viewing angles (privacy protection viewing angles), and thereby enhance privacy protection performance at large viewing angles (privacy protection viewing angles), as shown in FIG. 5.

For example, the first included angle θ2 may be 60°, 75°, 80°, and the like.

In this embodiment, the slope in each of the adjustment areas 161 may be determined by the slope of the pixel defining portion 121. Specifically, the height of the pixel defining portion 121 is 2 μm, and the pixel defining portion 121 also has a second inclined surface, that is, the pixel defining portion 121 is also provided with a slope. The inclination angle of the second inclined surface of the pixel defining portion 121 is the same as the inclination angle θ1 of the first inclined surface 162. That is, the slope of the pixel defining portion 121 determines the slope on the first encapsulation layer 160, and thus determines the inclination angle θ1 of the first inclined surface 162. By setting the height of the pixel defining portion 121, it is ensured that light rays may be emitted from the space between the pixel defining portion 121 and the light-shielding portion 142, guaranteeing the amount of emitted light rays, thereby ensuring the privacy protection performance.

FIG. 10 shows a schematic cross-sectional view of the third inclined surface adopting an arc surface structure.

Secondly, the light ray emitted by the dimming light-emitting portion 1411 tends to undergo diffraction or scattering on the edge of the light-shielding portion 142, resulting in light emission at small viewing angles (display viewing angles). At small viewing angles (display viewing angles), the dimming light emitted by the dimming light-emitting portion 1411 appears in the display, causing color interference with normal reading at small viewing angles (display viewing angles), thereby affecting the display performance at small viewing angles (display viewing angles).

Therefore, referring to FIG. 3 and FIG. 10, cross-sectional areas of each of the light-shielding portions 142 are gradually increased in the direction from the base substrate 110 to the display light-emitting portion 1311, so as to prevent the light ray emitted from the edge of the light-shielding portion 142 from interfering with the display performance at small viewing angles (display viewing angles).

In some embodiments of the present disclosure, referring to FIG. 3 or FIG. 10, each the light-shielding portions 142 has an upper surface 1420, a lower surface 1421, and a third inclined surface 1422 connecting the upper surface 1420 and the lower surface 1421. An orthographic projection of the lower surface 1421 on the base substrate 110 is located within an orthographic projection of the upper surface 1420 on the base substrate 110, such that when the light ray is diffracted or scattered on the edge of the lower surface 1421 of the light-shielding portion 142, the upper surface 1420 of the light-shielding portion 142 may completely block and absorb the scattered or diffracted light ray, preventing light emission at small viewing angles (display viewing angles), ensuring normal information reading at small viewing angles (display viewing angles), and thereby guaranteeing the display performance.

Second, the third inclined surface 1422 forms a second angle θ3 with an extension line of the lower surface 1421, and the second angle θ3 is less than or equal to the first angle θ2, so as to ensure that light at the optimal small viewing angle (display viewing angle) may be absorbed by the light-shielding portion 142, avoiding interference with information reading at small viewing angles (display viewing angles), thereby ensuring the display performance.

It is worth mentioning that the second angle θ3 may be less than or equal to the inclination angle θ1 of the first inclined surface 162, and the second angle θ3 may be 25°, 30°, 45°, 50°, and the like.

Furthermore, referring to FIG. 3, the third inclined surface 1422 may be a planar surface, in which case the cross-section of the light-shielding portion 142 in the thickness direction of the base substrate 110 is of an inverted trapezoidal structure. Referring to FIG. 10, the third inclined surface 1422 may also be an arc surface. When the third inclined surface 1422 is the arc surface, the second angle θ3 may be formed by a connection line between edge positions of the upper surface 1420 and the lower surface 1421 and the extension line of the lower surface 1421. Of course, the third inclined surface 1422 may also have other shapes, as long as the light-shielding portion 142 of the upper surface 1420 may block and absorb the diffracted or scattered light.

In some embodiments of the present disclosure, referring to FIG. 3 or FIG. 10, the display panel 100 further includes a second encapsulation layer 170 and a third encapsulation layer 180. The first encapsulation layer 160 and the third encapsulation layer 180 may be inorganic encapsulation layers, while the second encapsulation layer 170 may be an organic encapsulation layer. The second encapsulation layer 170 is disposed on a side of the first encapsulation layer 160 away from the base substrate 110, and the second encapsulation layer 170 has a planarization function. That is, the entire surface of the second encapsulation layer 170 away from the base substrate 110 is planar. The third encapsulation layer 180 is disposed on a side of the second encapsulation layer 170 away from the first encapsulation layer 160, and the above-mentioned light-shielding portion 142 is disposed on a side of the third encapsulation layer 180 away from the second encapsulation layer 170.

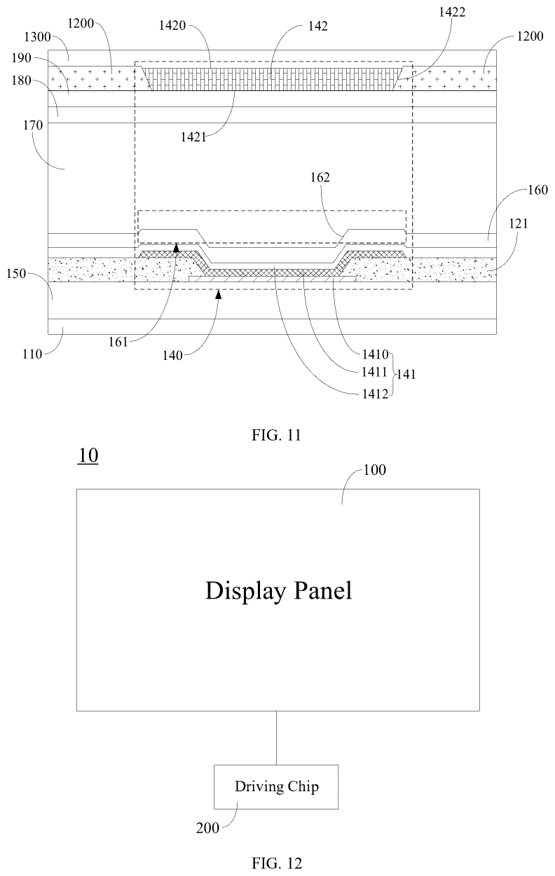

FIG. 11 shows a schematic cross-sectional view of the display panel further including a touch electrode layer, a color resist layer, and a planarization layer.

In some embodiments of the present disclosure, referring to FIG. 11, the display panel 100 further includes a touch electrode layer 190. The touch electrode layer 190 is disposed on a side of the third encapsulation layer 180 away from the second encapsulation layer 170, and the light-shielding portion 142 is disposed above the touch electrode layer 190. Touch display may be achieved through this touch electrode layer 190.

In some embodiments of the present disclosure, referring to FIG. 11, the display panel 100 further includes a color resist layer 1100. The color resist layer 1100 is disposed on a side of the touch electrode layer 190 away from the base substrate 110, and the color resist layer 1100 includes a plurality of color resist units 1110, each of the plurality of color resist units 1110 corresponding to a display light-emitting diode 131.

That is, referring to FIG. 2, the display panel 100 adopts color filter on encapsulation (COE) technology, i.e., a color resist unit 1110 corresponding to the light-emitting color is formed on a light-emitting side of the display light-emitting diode 131, the light-shielding portion 142 and the color resist unit 1110 are located in the same layer, and the light-shielding portion 142 is located between adjacent color resist units 1110. The light-shielding portion 142 may efficiently absorb ambient light across all wavelengths, and the plurality of color resist units 1110 may include R (red), G (green), and B (blue) color resist units 1110, ensuring that 80% or even higher proportion of the display light rays emitted by the organic light-emitting material layer pass through. While the color is further purified, the light-shielding portion may also effectively absorb other wavelength light rays in ambient light rays that do not correspond to the primary color, thus eliminating the need for a circular polarizer and reducing the reflection of the ambient light rays by the display panel 100, resulting in better contrast and more accurate, wider color performance.

It should be understood that a light-transmitting area is formed between the light-shielding portion 142 of the dimming structure 140 and the color resist unit 1110 of the adjacent display light-emitting structure 130, such that the light rays from the dimming light-emitting portion 1411 blocked by the light-shielding portion may be emitted to the external environment, mixing with the light rays emitted by the adjacent display light-emitting diode 131, resulting in color mixing and interfering with information reading. In other words, the display image seen at an oblique viewing angle is a privacy protection image.

To achieve privacy protection at different viewing angles, the size of the light-transmitting area between the light-shielding portion 142 and the color resist unit 1110 may be adjusted as needed.

Furthermore, referring to FIG. 11, the display panel 100 further includes color filter units 1200. Each of the color filter units 1200 is disposed between the light-shielding portion 142 and the color resist unit 1110, that is, each of the color filter units 1200 may be disposed within the above-mentioned light-transmitting area. Each of the color filter units 1200 is disposed around the light-shielding portion 142 to ensure that the light ray emitted from the dimming light-emitting portion 1411 passes completely through a corresponding color filter unit 1200 before being emitted. Each of the color filter units 1200 may be disposed in the same layer as the plurality of color resist units 1110 in the color resist layer 1100, that is, the color filter unit 1200 may be fabricated simultaneously with the plurality of color resist units 1110, thereby reducing the manufacturing cost.

It should be noted that each of the colors of the color filter units 1200 is the same as the color of the light ray emitted by a corresponding dimming light-emitting portion 1411, so as to improve the purity of the light ray emitted by the dimming light-emitting portion 1411 and enhance the privacy protection effect.

In addition, when the color filter unit 1200 and the light-shielding portion 142 are prepared, the color filter unit 1200 may be prepared first, and then an inclined or arc surface may be formed on the edge of the color filter unit 1200, followed by the preparation of the light-shielding portion 142, so as to ensure a seamless connection between the light-shielding portion 142 and the color filter unit 1200. This simplifies the manufacturing process and also ensures that the light rays emitted by the dimming light-emitting portion 1411 may pass completely through the color filter unit 1200, guaranteeing the light ray purity.

In this embodiment, referring to FIG. 11, the display panel 100 further includes a planarization layer 1300. The planarization layer 1300 is disposed on a side of the color resist layer 1100 away from the base substrate 110, and covers the plurality of color resist units 1110, the color filter unit 1200, and the light-shielding portion 142, serving a planar insulation function.

The display panel 100 of the present disclosure has at least the following advantageous effects.

The display panel 100 in the solution of the present disclosure includes the base substrate 110, and the pixel defining layer 120, the plurality of display light-emitting structures 130, the plurality of dimming structures 140, and the first encapsulation layer 160 disposed on the base substrate 110. The pixel defining layer 120 defines pixel defining portions 121 and the plurality of pixel openings 122 spaced apart from each other, and each of the pixel defining portions 121 is located between the adjacent pixel openings 122. Each of the plurality of display light-emitting structures 130 includes the display light-emitting diode 131, which includes the display light-emitting portion 1311 for emitting a display light ray. The dimming structure 140 includes the dimming light-emitting diode 141 and the light-shielding portion 142, with the dimming light-emitting diode 141 disposed between the adjacent display light-emitting diodes 131. The dimming light-emitting diode 141 includes the dimming light-emitting portion 1411 for emitting a privacy protection light ray, and the light-shielding portion 142 is located on the side of the dimming light-emitting diode 141 away from the base substrate 110. The orthographic projection of the dimming light-emitting portion 1411 on the base substrate 110 is within the orthographic projection of the light-shielding portion 142 on the base substrate 110. The first encapsulation layer 160 is disposed on the side of the light-shielding portions 142 toward the base substrate 110, and is configured to cover the display light-emitting diodes 131, the dimming light-emitting diodes 141, and the pixel defining layer 120. The first encapsulation layer 160 includes adjustment areas 161 corresponding to the dimming structures 140, and each of the adjustment areas 161 is provided with the first inclined surface 162 with the inclination angle ranging from 35° to 50°. The dimming light-emitting portion 1411 located on the edge of the pixel opening 122 may emit the light ray parallel to the inclination angle of the first inclined surface 162, which may form the light-emitting point A with the top surface of one of the adjustment areas 161. The line connecting the light-emitting point A and the bottom edge of the light-shielding portion 142 forms the first included angle with the top surface of the first encapsulation layer 160, and the first included angle is greater than or equal to the inclination angle of the first inclined surface 162. In this way, most of the privacy protection light rays emitted by the dimming light-emitting portion 1411 may be mixed with the display light rays emitted by the display light-emitting portion 1311, reducing the light output of the dimming light-emitting portion 1411 at small viewing angles, increasing the light output at large viewing angles, and improving the amount of privacy protection light rays emitted at privacy protection angles, thereby enhancing the privacy protection effect at privacy angles.

### Embodiment II

FIG. 12 shows a schematic structural diagram of a connection between the display panel and the driving chip.

Referring to FIG. 12, Embodiment II of the present disclosure provides a display device 10. The display device 10 includes a driving chip 200 and the display panel 100 in Embodiment I. The display panel 100 is electrically connected to the driving chip 200.

According to the embodiments of the present disclosure, the specific type of the display device 10 is not particularly limited, and any commonly used type of display device 10 in the field may be adopted, such as a display screen, a mobile phone, a notebook computer, and another mobile device, a watch and another wearable device, a virtual reality (VR) device, and the like. Those skilled in the art may select accordingly based on the specific disclosure of t he display device, and further details are omitted here.

In the description of this specification, references to terms such as “some embodiments” and “exemplarily” mean that the specific features, structures, materials, or characteristics described in connection with the embodiment or example are included in at least one embodiment or example of the present disclosure. In this specification, the illustrative expressions of the above terms do not necessarily refer to the same embodiment or example. Moreover, the specific features, structures, materials, or characteristics described may be combined in any suitable manner in one or more embodiments or examples. Furthermore, those skilled in the art may combine and integrate different embodiments or examples and respective features thereof described in this specification without conflict.

Although the embodiments of the present disclosure have been shown and described above, it should be understood that these embodiments are exemplary and should not be construed as limiting the present disclosure. Those of ordinary skill in the art may make changes, modifications, substitutions, and alterations to the above embodiments within the scope of the present disclosure. Therefore, any changes or modifications made according to the claims and specification of the present disclosure should fall within the scope covered by the present patent disclosure.

What is claimed is:

1. A display panel, comprising a base substrate, the base substrate having a display area, wherein the display panel further comprises:
a pixel defining layer provided with pixel defining portions and a plurality of pixel openings spaced apart from each other, each of the pixel defining portions being located between adjacent pixel openings, and in a direction from the base substrate to the pixel defining layer, distances between adjacent pixel defining portions gradually increasing;
a plurality of display light-emitting structures, each of the plurality of display light-emitting structures comprising a display light-emitting diode, the display light-emitting diode comprising a display light-emitting portion, and at least part of the display light-emitting portion being located within one of the plurality of pixel openings;
a plurality of dimming structures, each of the plurality of dimming structures being disposed between adjacent display light-emitting structures; and each of the plurality of dimming structures comprising a dimming light-emitting diode and a light-shielding portion, wherein the dimming light-emitting diode comprises a dimming light-emitting portion, and at least part of the dimming light-emitting portion is located within one of the plurality of pixel openings; the light-shielding portion being located on a side of the dimming light-emitting diode away from the base substrate; an orthographic projection of the dimming light-emitting portion on the base substrate being located within an orthographic projection of the light-shielding portion on the base substrate; and a light-emitting color of the dimming light-emitting portion being different from a light-emitting color of at least one display light-emitting portion adjacent to the dimming light-emitting portion; and
a first encapsulation layer disposed on a side of the light-shielding portion toward the base substrate, and configured to cover the display light-emitting diode, the dimming light-emitting diode, and the pixel defining layer, wherein the first encapsulation layer comprises adjustment areas, and an orthographic projection of each of the adjustment areas on the base substrate is located within an orthographic projection of the light-shielding portion on the base substrate; wherein each of the adjustment areas is provided with a first inclined surface, and an inclination angle of the first inclined surface ranges from 35° to 50°;
wherein the dimming light-emitting portion located on an edge of each of the plurality of pixel openings emits a light ray parallel to the inclination angle of the first inclined surface, the light ray forming a light-emitting point with a top surface of one of the adjustment areas, and a line connecting the light-emitting point and a bottom edge of the light-shielding portion forming a first included angle with a top surface of the first encapsulation layer, wherein the first included angle is greater than or equal to the inclination angle of the first inclined surface.

2. The display panel of claim 1, wherein each of the pixel defining portions is provided with a second inclined surface, and an inclination angle of the second inclined surface is same as the inclination angle of the first inclined surface.

3. The display panel of claim 1, wherein a height of each of the pixel defining portions is 2 μm.

4. The display panel of claim 1, wherein cross-sectional areas of the light-shielding portion gradually increase in a direction from the base substrate to the display light-emitting portion.

5. The display panel of claim 4, wherein the light-shielding portion has a second included angle less than or equal to the first included angle, and the second included angle is less than or equal to the inclination angle of the first inclined surface.

6. The display panel of claim 1, further comprising:
a second encapsulation layer; and
a third encapsulation layer disposed on a side of the second encapsulation layer away from the first encapsulation layer, and the light-shielding portion being disposed on a side of the third encapsulation layer away from the base substrate;
wherein the second encapsulation layer and the third encapsulation layer are stacked in sequence.

7. The display panel according to claim 6, further comprising a touch electrode layer disposed on a side of the third encapsulation layer away from the second encapsulation layer, and the light-shielding portion being disposed on a side of the touch electrode layer away from the third encapsulation layer.

8. The display panel of claim 7, further comprising a color resist layer disposed on a side of the touch electrode layer away from the base substrate, the color resist layer comprising a plurality of color resist units, and each of the plurality of color resist units corresponding to one display light-emitting diode.

9. The display panel of claim 8, further comprising color filter units in a same layer as the plurality of color resist units, wherein each of the color filter units is disposed between the light-shielding portion and one of the plurality of color resist units, and a color of each of the color filter units is same as a color of a light ray emitted by a corresponding dimming light-emitting portion.

10. The display panel of claim 1, wherein the display light-emitting diode comprises a display anode, the display light-emitting portion, and a display cathode stacked in sequence in a direction away from the base substrate;
wherein the dimming light-emitting diode comprises a dimming anode, the dimming light-emitting portion, and a dimming cathode stacked in sequence in the direction away from the base substrate;
wherein the dimming anode is arranged in a same layer as the display anode, and the dimming anode is disconnected from the display anode, such that the dimming light-emitting diode and the display light-emitting diode are independently controlled.

11. The display panel of claim 10, wherein in a case that the display panel is in a normal display mode, the display light-emitting diode is controlled to emit light, and the dimming light-emitting diode is controlled not to emit light;
wherein in a case that the display panel is switched from the normal display mode to a privacy protection display mode, both the display light-emitting diode and the dimming light-emitting diode are controlled to emit light.

12. A display device, comprising:
a driving chip; and
a display panel electrically connected to the driving chip;
wherein the display panel comprises a base substrate, and the base substrate has a display area, wherein the display panel further comprises:
a pixel defining layer provided with pixel defining portions and a plurality of pixel openings spaced apart from each other, each of the pixel defining portions being located between adjacent pixel openings, and in a direction from the base substrate to the pixel defining layer, distances between adjacent pixel defining portions gradually increasing;
a plurality of display light-emitting structures, each of the plurality of display light-emitting structures comprising a display light-emitting diode, the display light-emitting diode comprising a display light-emitting portion, and at least part of the display light-emitting portion being located within one of the plurality of pixel openings;
a plurality of dimming structures, each of the plurality of dimming structures being disposed between adjacent display light-emitting structures; and each of the plurality of dimming structures comprising a dimming light-emitting diode and a light-shielding portion, wherein the dimming light-emitting diode comprises a dimming light-emitting portion, and at least part of the dimming light-emitting portion is located within one of the plurality of pixel openings; the light-shielding portion being located on a side of the dimming light-emitting diode away from the base substrate; an orthographic projection of the dimming light-emitting portion on the base substrate being located within an orthographic projection of the light-shielding portion on the base substrate; and a light-emitting color of the dimming light-emitting portion being different from a light-emitting color of at least one display light-emitting portion adjacent to the dimming light-emitting portion; and
a first encapsulation layer disposed on a side of the light-shielding portion toward the base substrate, and configured to cover the display light-emitting diode, the dimming light-emitting diode, and the pixel defining layer, wherein the first encapsulation layer comprises adjustment areas, and an orthographic projection of each of the adjustment areas on the base substrate is located within an orthographic projection of the light-shielding portion on the base substrate; wherein each of the adjustment areas is provided with a first inclined surface, and an inclination angle of the first inclined surface ranges from 35° to 50°;
wherein the dimming light-emitting portion located on an edge of each of the plurality of pixel openings emits a light ray parallel to the inclination angle of the first inclined surface, the light ray forming a light-emitting point with a top surface of one of the adjustment areas, and a line connecting the light-emitting point and a bottom edge of the light-shielding portion forming a first included angle with a top surface of the first encapsulation layer, wherein the first included angle is greater than or equal to the inclination angle of the first inclined surface.

13. The display device of claim 12, wherein each of the pixel defining portions is provided with a second inclined surface, and an inclination angle of the second inclined surface is same as the inclination angle of the first inclined surface.

14. The display device of claim 12, wherein a height of each of the pixel defining portions is 2 μm.

15. The display device of claim 12, wherein cross-sectional areas of the light-shielding portion gradually increase in a direction from the base substrate to the display light-emitting portion.

16. The display device of claim 15, wherein the light-shielding portion has a second included angle less than or equal to the first included angle, and the second included angle is less than or equal to the inclination angle of the first inclined surface.

17. The display device of claim 12, wherein the display panel further comprises:
a second encapsulation layer; and
a third encapsulation layer disposed on a side of the second encapsulation layer away from the first encapsulation layer, and the light-shielding portion being disposed on a side of the third encapsulation layer away from the base substrate;
wherein the second encapsulation layer and the third encapsulation layer are stacked in sequence.

18. The display device of claim 17, wherein the display panel further comprises a touch electrode layer disposed on a side of the third encapsulation layer away from the second encapsulation layer, and the light-shielding portion being disposed on a side of the touch electrode layer away from the third encapsulation layer.

19. The display device of claim 18, wherein the display panel further comprises a color resist layer disposed on a side of the touch electrode layer away from the base substrate, the color resist layer comprising a plurality of color resist units, and each of the plurality of color resist units corresponding to one display light-emitting diode.

20. The display device of claim 19, wherein the display panel further comprises color filter units in a same layer as the plurality of color resist units, wherein each of the color filter units is disposed between the light-shielding portion and one of the plurality of color resist units, and a color of each of the color filter units is same as a color of a light ray emitted by a corresponding dimming light-emitting portion.
